(19) United States
(12) Patent Application Publication
(10) Pub. No.: US 2014/0110607 A1
(43) Pub. Date: Apr. 24, 2014

(54) ION IMPLANTER POWER SUPPLY WHICH IS INTENDED TO LIMIT THE LOADING EFFECT

(71) Applicants: FRANK Torregrosa, Simiane (FR); Mathieu Gilles, Marseille (FR)

(72) Inventors: FRANK Torregrosa, Simiane (FR); Mathieu Gilles, Marseille (FR)

(73) Assignee: ION BEAM SERVICES, PEYNIER (FR)

(21) Appl. No.: 14/007,099

(22) PCT Filed: Jun. 14, 2005
(86) PCT No.: PCT/FR2005/001466

§ 371 Date: Sep. 24, 2013

(30) Foreign Application Priority Data
Apr. 16, 2004 (FR) 0406495

(51) Int. Cl. H03H 7/06; H01J 37/317

(52) U.S. Cl. CPC H03H 7/06; H01J 37/3171
USPC 250/492.3; 333/172

(57) ABSTRACT

The invention relates to a power supply ALT for an ion implanter, the power supply comprising: an electricity generator SOU placed between a substrate-carrier tray PPS and ground E, and a capacitor CDS in a parallel branch likewise connected between the substrate-carrier tray PPS and ground E. The capacitor CDS has a capacitance of less than 5 nF. The invention also provides an ion implanter incorporating the power supply.

The present invention relates to an ion implanter power supply designed to limit the charge effect.

The field of the invention is that of ion implanters operating in plasma immersion mode. Thus, implanting ions in a substrate consists in immersing the substrate in a plasma and in biasing it with a negative voltage, in the range a few tens of volts to a few tens of kilovolts (generally less than 100 kV), in order to create an electric field capable of accelerating ions from the plasma towards the substrate.

The depth to which ions penetrate is determined by their acceleration energy. It depends firstly on the voltage applied to the substrate and secondly on the respective natures of the ions and of the substrate. The concentration of implanted atoms depends on the dose that is expressed in terms of number of ions per square centimeter (cm²) and on the implantation depth.

For reasons associated with the physics of plasmas, a few nanoseconds after the voltage is applied, an ion sheath is created around the substrate. The potential difference responsible for accelerating ions towards the substrate is the difference to be found across this sheath.

The growth of this sheath as a function of time satisfies the Child-Langmuir law:

$${j}_{c} = \frac{4}{9} {{ɛ}_{0} ( \frac{2 e}{M} )}^{1 / 2} \frac{{V}_{0}^{3 / 2}}{{s}^{2}}$$

where:

j_{c}=current density;

eₐ=permittivity of free space;

e=ion charge;

M=ion mass;

V₀=potential difference through the sheath; and

s=thickness of the sheath.

By stipulating that the current density is equal to the charge passing through the boundary of the sheath per unit time, ds/dt represents the displacement of said boundary:

$$\frac{d s}{d t} = \frac{2}{9} \frac{{s}_{0}^{2} \cdot {u}_{0}}{{s}^{2}}$$

In which the expression s₀ is given by:

$${s}_{0} = {( \frac{2 {ɛ}_{0} {V}_{0}}{e \cdot {n}_{0}} )}^{1 / 2}$$

it being understood that u₀=(2 eV₀/M) is the characteristic speed of the ion and that n₀ is the density of the plasma.

The thickness of the sheath is associated mainly with the applied voltage, the density of the plasma, and the mass of the ions.

The equivalent impedance of the plasma, which conditions implantation current, is directly proportional to the square of the thickness of the sheath. Implantation current thus decreases very quickly when the sheath becomes larger.

After a certain amount of time has elapsed, it is necessary to reinitialize. In practice this is found to be essential when the sheath reaches the walls of the enclosure, thereby stopping the implantation mechanism.

In order to reinitialize the system, almost all implanter manufacturers disconnect the high voltage from the substrate while keeping the plasma ignited. It is therefore necessary to have a pulse generator that produces high-voltage pulses.

Furthermore, implantation requires acceleration energy to be as stable as possible, and consequently it is appropriate to satisfy the following specifications:
rise and fall times less than 1 microsecond (μs);
high voltage stable during the pulse;
instantaneous current very high in the range 1 amp (A) to 300 A; and
ability to accommodate arcing in the plasma.

Ion implantation in plasma immersion mode presents a certain number of drawbacks.

Firstly, pulsed high voltage power supplies are very expensive, often fragile, and have a direct influence on the quality of the implantation performed.

Secondly, the continuous presence of the plasma in the enclosure gives rise to undesirable side effects:
particle generation;
heat delivered to the substrate;
the enclosure is attacked, giving rise to a risk of metal contamination of the parts being processed; and
charge effects are created, which can be particularly troublesome in microelectronic applications.

In order to reduce those side effects, the supplier Varian has proposed a pulsed plasma process referred to as plasma doping (PLAD). That process is described in two articles of the journal Surface and Coatings Technology, No. 156 (2002) “Proceedings of the VIth international workshop on plasma-based ion implantation (PBII-2001), Grenoble, France, Jun. 25-28, 2001” published by Elsevier Science B.V.:
S. B. Felch et al., “Plasma doping for the fabrication of ultra-shallow junctions”, pp. 229-236; and
D. Lenoble et al., “The fabrication of advanced transistors with plasma doping”, pp. 262-266.

That method also consists in biasing the substrate with high voltage pulses. Nevertheless, the electric field created between the substrate and the ground electrode situated facing it enables the plasma to be pulsed. The field lines around the substrate enable ions to be accelerated and implanted. In that method, the pulsed plasma makes it possible to avoid some of the above-described side effects, but the constraints associated with using a high voltage pulsed generator still remain. Furthermore, the characteristic of the plasma cannot be separate from the bias voltage. As a result, the machine is not very versatile: it presents a small range of acceleration voltages and it is always difficult to implant species that do not lend themselves to forming plasmas.

Using a different approach, U.S. Pat. No. 5,558,718 teaches apparatus and a method for implanting ions having a source of pulses. That ion implantation apparatus does not have a high voltage pulse generator. It makes use of a pulsed plasma source and a power generator that delivers a constant voltage for biasing the target.

When using large targets that require high currents, a bypass branch provided with a capacitor high capacitance and a series resistor is connected in parallel with the power generator since it is important for the voltage applied to the target to be as stable as possible during the implantation stage.

Firstly, the large flux of ions created by implantation leads to positive charge accumulating on the insulating zones of the substrate (surface oxides, insulating deposits on the surface, deposited polymers such as photolithographic resins, . . . ), which phenomenon is particularly acute in the field of microelectronics. This accumulation of charge leads to an uncontrolled increase in the potential of these insulating zones. When the potential difference between such an insulating zone and a conductive zone of the substrate reaches a critical threshold, an electric arc is struck that leads to local destruction of the substrate.

The problem associated with this accumulation of charge in conventional so-called “high-current” implanters has been solved when the substrates are located in positions that are free from any strong electric field. Under such circumstances, it is possible to use electron guns to neutralize the positive charge caused by the implanted ion flux. Nevertheless, that solution cannot be applied if the substrate is biased with a negative high voltage. In addition, an electron gun would lead to metallic contamination.

A first object of the invention is thus to limit the effect of charge in an implanter operating in pulsed plasma mode.

In response to this first object, an ion implanter power supply comprises an electricity generator disposed between a substrate-carrier tray and ground, and also comprises a capacitor in a parallel branch also connected between the substrate-carrier tray and ground; in addition, the capacitor presents capacitance of less than 5 nanofarads (nF).

The power supply is thus made in such a manner as to limit the charge effect. The capacitor CDS presents capacitance of low value so that the voltage across its terminals tends progressively towards zero while it is discharging.

Secondly, the power generator consumes a large amount of energy. It should be designed in such a manner as to be adapted to the volume of the target to be ionized, and the time constant of the parallel branch should be greater than the duration of a pulse delivered by the plasma source.

A second object of the invention is thus to improve this situation.

In response to this second object, the parallel branch comprises no more than the capacitor.

The resistor that lies behind the above-mentioned constraints is omitted.

In a first embodiment, the generator is a voltage generator and the power supply includes a load impedance in series therewith.

This load impedance is preferably a resistance lying in the range 200 kilohms (kΩ) to 2000 kΩ.

Advantageously, the voltage delivered by the generator lies in the range −100 V to −10,000 V.

In a second embodiment of the power supply, the generator is a current generator.

Advantageously, the voltage delivered by the generator then lies in the range −100 V to −100,000 V.

The invention is preferably applied to an ion implanter including a power supply as specified above and a pulsed plasma source, the implanter including means for ensuring that the duration of the plasma pulse emitted by the pulsed plasma source lies in the range 20 μs to 5000 μs.

When the generator of the power supply is a current generator, it is desirable for the implanter to include means for inhibiting the generator during a plasma pulse.

Whatever the type of generator adopted, according to an additional characteristic, the electrical impedance of the plasma Zp lies in the range 30 kΩ to 300 kΩ and the working pressure is less than 5×10⁻³ millibars (mbar).

Furthermore, the capacitance C of the capacitor, the duration tp of the pulse produced by the pulsed plasma source, the impedance of the plasma, the inversion voltage Vᵢₙᵥ and the power supply voltage Vₚₛ delivered by the generator are related by the following equation:

C/tp<−1/(Zp.ln(Vᵢₙᵥ/Vₚₛ)

Preferably, the substrate-carrier tray is rotatable about its axis.

In addition, the substrate-carrier tray and the pulsed plasma source present an adjustable offset between their axes.

The present invention is described below in greater detail in the following description of an embodiment given by way of illustration and referring to the accompanying drawings, in which:

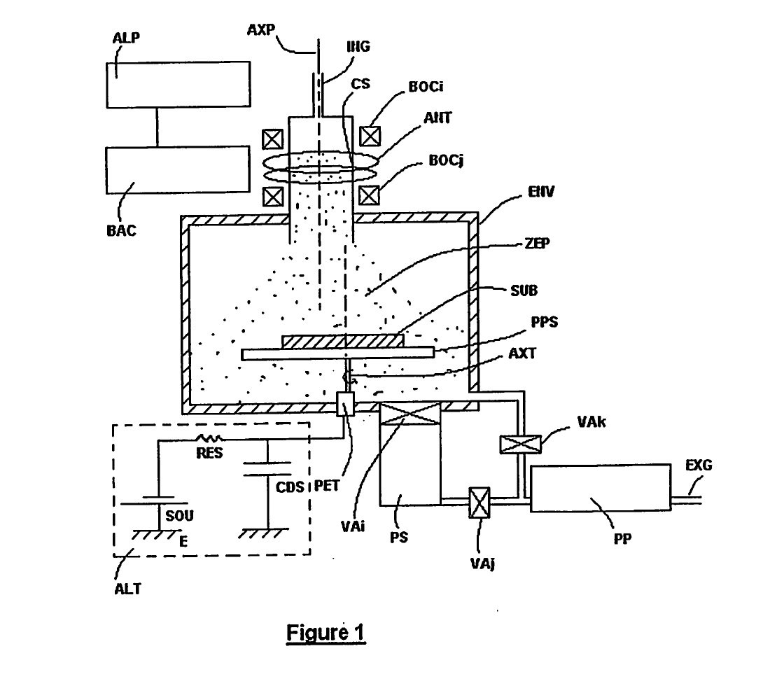

FIG. 1 shows an implanter in diagrammatic vertical section;

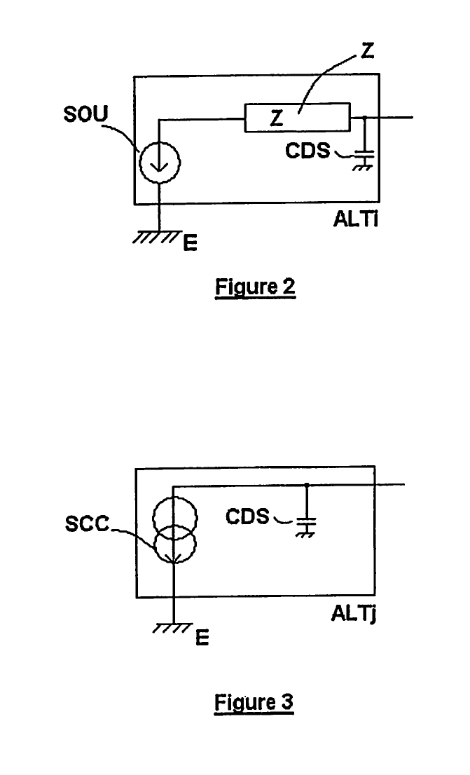

FIG. 2 shows a first variant power supply for the substrate-carrier tray; and

FIG. 3 shows a second variant power supply for the tray.

Elements present in more than one of the figures are given the same references in all of them.

As shown in FIG. 1, an ion implanter comprises a plurality of elements arranged inside and outside a vacuum enclosure ENV. For microelectronic applications, it is recommended to use an enclosure made of aluminum alloy if it is desired to limit contamination by metallic elements such as iron, chromium, nickel, or cobalt. It is also possible to use a coating of silicon or of silicon carbide.

A substrate-carrier tray PPS in the form of a horizontal plane disk that can be rotated about its vertical axis AXT receives the substrate SUB that is to be subjected to ion implantation.

A high voltage electrical bushing PET provided through the bottom portion of the enclosure ENV electrically connects a power supply ALT to the tray vertical axis AXT, and thus to the substrate-carrier tray PPS.

Conventionally, this substrate-carrier power supply ALT comprises a direct voltage generator SOU whose positive terminal is connected to ground. A bypass branch is connected in parallel with the generator, said branch being constituted by a capacitor CDS in series with a resistor RES.

Pump means PP, PS are also connected to the bottom portion of the enclosure ENV. A primary pump PP has its inlet connected to the enclosure ENV by a pipe having a valve VAk, and its outlet connected to the atmosphere via an exhaust pipe EXG. A secondary pump PS has its inlet connected to the enclosure ENV via a pipe provided with a valve VAi, and its outlet connected to the inlet of the primary pump PP via a pipe provided with a valve VAj. These pipes are not referenced themselves.

The top portion of the enclosure ENV receives a source body CS that is cylindrical about a vertical axis AXP. The body is made of quartz. It is surrounded externally firstly by confinement coils BOCi, BOCj, and secondly by an outer radiofrequency (RF) antenna ANT. The antenna is electrically connected via a tuning box BAC to a pulsed RF source ALP. The plasma-forming gas inlet ING is coaxial about the vertical axis AXP of the source body CS. This vertical axis AXP intersects the surface of the substrate-carrier tray PPS on which the substrate SUB for implanting is placed.

It is possible to use any type of pulsed plasma source: discharge; inductively-coupled plasma (ICP); Helicon; microwave; arc. These sources must work at pressure levels that are low enough to ensure that the electric field created between the tray PPS at high voltage and the enclosure ENV at ground potential does not ignite a discharge plasma that would disturb the pulsed operation of the source.

The source that is selected must make it possible to have a plasma potential close to zero. The ion acceleration energy is the difference between the potential of the plasma and the potential of the substrate. The acceleration energy is then controlled solely by the voltage applied to the substrate. This point becomes predominant when it is desired for the acceleration energies to be very low, less than 500 electron volts (eV), as is true for microelectronic applications.

For applications that require low levels of metallic contamination, such as microelectronics, again, and processing items for medical applications, the source must not present any contaminating metal element in contact with the plasma. In the embodiment described, an RF source constituted by a quartz tube is associated with an external RF antenna ANT and with magnetic confinement coils BOCi, BOCj, as described above.

Any plasma-generating species can be implanted. This can be done from a gaseous precursor such as N₂, O₂, He, Ar, BF₃, B₂H₆, AsH₃, PH₃, SiH₄, C₂H₄, a liquid precursor such as TiCl₄, H₂O, or a solid precursor. With a solid precursor, it is appropriate to use a thermal evaporation system (phosphorus) or a hollow cathode arc system.

The method of implantation using the implanter comprises periodically repeating the following four or five stages:
a stage of charging the capacitor CDS (while the plasma source ALPL is extinguished) by means of the generator SOU until a discharge voltage is obtained;
a stage of igniting the plasma which is initiated when the voltage of the substrate reaches the discharge voltage: since the impedance of the plasma is no longer infinite, the capacitor CDS discharges therethrough;
a stage of discharging the capacitor CDS, during which implantation is performed, and during which the sheath becomes extended; and
a stage of extinguishing the plasma which is initiated when the preceding stage has lasted for the desired length of time: the impedance of the plasma is again infinite and the charging stage can be reiterated;
an optional waiting stage during which nothing happens, thereby enabling the repetition period to be adjusted.

During the discharge stage, which lasts for the duration of a plasma pulse, a plasma extension zone ZEP constituted by an ionized gas cloud forms between the source body CS and the substrate-carrier tray PPS. The particles strike the substrate SUB for implanting with energy that enables them to penetrate into the substrate SUB.

In the invention, the substrate-carrier power supply ALT is made in such a manner as to limit the charge effect. To do this, the capacitor CDS presents capacitance of small value so as to cause the potential of the substrate to return progressively to a value that is close to zero during the capacitor-discharge stage.

Even though using a pulsed plasma serves to limit the charge effect, the problem remains, particularly if the potential of the substrate is very negative during the process (as when using a capacitor of large capacitance).

When using a capacitor of small capacitance and a plasma pulse of sufficient length, the following phenomena occur:
at the beginning of the pulse, the capacitor is charged, the potential of the substrate is set by the voltage to which the capacitor is charged, and the ions are accelerated towards the substrate by the mechanism as described above;
the voltage across the terminals of the capacitor drops since it discharges into the plasma; and
above a certain potential, referred to herein as the inversion potential, the positive charge that has accumulated on the insulating zones generate an electric field that then becomes predominant and attracts the electrons of the plasma; this neutralizes the positive charge and eliminates any risk of arcing.

The neutralization is particularly effective when the working pressure is low. If the mean free path length of the electrons is great, then the electron flux reaching the surface in order to neutralize the charge effect is itself likewise considerable.

The conditions necessary for establishing this mechanism are thus as follows:
the capacitance of the capacitor CDS is sufficiently small;
the duration of the plasma pulse is long enough to reach the inversion potential before the charge that accumulates on the surface gives rise to arcing; and
the working pressure is small enough for the mean free path of the electrons created by the plasma source to allow them to reach the substrate without risk of collision and recombination with the gas molecules and ions present in the enclosure.

By way of example, the following parameters can be adopted:
the capacitor CDS has capacitance C lying in the range 300 picofarads (pF) to 5 nF;
the duration tp of the plasma pulse lies in the range 20 μs to 5000 μs, and preferably in the range 20 μs to 500 μs;
the inversion voltage Vᵢₙᵥ of the ion flux generated in the implanter lies in the range −20 V to −200 V (this inversion voltage depends on the amount of positive charge stored on the insulating zones of the substrate);
the electrical impedance Zp of the plasma generated in the pulse lies in the range 30 kΩ to 300 kΩ (this impedance depends on the adjustment of the plasma source);
the voltage Vₚₛ delivered by the generator lies in the range −100 V to −10,000 V, and preferably in the range −100 V to −5000 V;
the working pressure within the implanter is less than 5×10⁻³ mbar, and preferably less than 2×10⁻³ mbar; and
the plasma pulse repetition frequency lies in the range 1 Hz to 500 Hz.

The value of the inversion voltage Vᵢₙᵥ corresponds to the value of the potential to be reached during discharge of the capacitor CDS in order to suppress arcing.

The value Zp of the equivalent impedance of the plasma depends on the density of the plasma which in turn depends on the pressure.

It is assumed that the current recharging the capacitor CDS during the plasma pulse is negligible, i.e. that the load resistor Z in series with the voltage generator SOU presents very high resistance.

It is necessary during a plasma pulse for the bias voltage Vₚₗₐ to return to a value that is greater than the voltage Vᵢₙᵥ for inverting the ion/electron flux:

Vₚₗₐ>Vᵢₙᵥ

Given that:

Vₚₗₐ=Vₚₛe^{-tp/Zp.C}

it follows that the relationship between the minimum duration tp of the plasma pulse and the maximum value of the capacitance C is given by:

C/tp<−1/(Zp.ln(Vᵢₙᵥ/Vₚₛ)

where ln stands for natural logarithm.

It is therefore appropriate to seek plasma pulses of long duration tp and/or a capacitor of small capacitance C.

With the following values:
ion flux inversion voltage Vᵢₙᵥ=−60 V;
voltage delivered by the voltage generator SOU=−1000 V;
electrical impedance Zp of the plasma=100 kΩ; and
plasma pulse duration tp=100 μs;

then the capacitance C must not exceed 350 pF.

The invention also seeks to further improve the performance of the substrate-carrier power supply ALT.

With reference to FIG. 2, in a first embodiment, the substrate-carrier power supply is in the form of a tray power supply ALTi comprising a load impedance Z having a first terminal connected to the negative terminal of the direct voltage generator SOU. The second terminal of the load impedance is connected to the substrate-carrier tray PPS and to the first terminal of the capacitor CDS whose second terminal is connected to ground.

The load impedance Z is often a resistance serving to limit current when beginning to charge the capacitor CDS. In addition, if this resistance is greater than the equivalent impedance of the plasma, it also serves to limit recharging of the capacitor during the plasma pulse when it is desired to discharge the capacitor.

For a typical plasma impedance equal to 100 kΩ, the load resistance preferably lies in the range 200 kΩ to 2000 kΩ. The capacitance of the capacitor CDS is such that it is discharged almost completely at the end of a plasma pulse.

The parameters commonly used in this embodiment are as follows:
plasma density lying in the range 10⁸ ions per cubic centimeter (ions/cm³) to 10¹⁰ ions/cm³;
plasma pulse duration lying in the range 15 μs to 500 μs;
frequency of pulse repetition lies in the range 1 Hz to 3 kHz;
working pressure lies in the range 2×10⁻⁴ mbar to 5×10⁻³ mbar;
gas used: N₂, BE₃, O₂, H₂, PH₃, AsH₃, or Ar;
load impedance Z constituted by resistance greater than 300 kΩ;
capacitance C of 500 pF; and
bias voltage lying in the range −100 V to −10,000 V.

With reference to FIG. 3, in a second embodiment, the substrate-carrier power supply is in the form of a tray power supply ALTj comprising a direct current generator SCC having a first terminal connected to ground. The first terminal of the capacitor CDS is connected to the substrate-carrier tray PPS and to the second terminal of the current generator SCC, while its second terminal is connected to ground.

It is desirable for the current generator SCC to be inhibited during the plasma pulse, or in other words for the capacitor CDS not to be powered by the generator during said pulse. By way of example, it is possible to provide a switch (not shown) connecting the second terminal of the generator SCC either to the first terminal of the capacitor CDS (as described above) in the absence of a plasma pulse, or else to the first terminal of a resistance (not shown) during a plasma pulse, the second terminal of the resistance being connected to ground. Advantageously, it is possible to make use of the inhibit mode that is provided on most chopper generators.

When the current generator SCC is inhibited, the above relationship between the minimum duration tp of the plasma pulse and the maximum capacitance C continues to apply:

C/tp<−1/(Zp.ln(Vᵢₙᵥ/Vₚₛ))

The parameters commonly used in this embodiment are as follows:
plasma density lying in the range 10⁸ ions/cm³ to 10¹⁰ ions/cm³;
plasma pulse duration lying in the range 15 μs to 500 μs;
frequency of pulse repetition lies in the range 1 Hz to 3 kHz;
working pressure lies in the range 2×10⁻⁴ mbar to 5×10⁻³ mbar;
gas used: BF₃, PH₃, AsH₃, N₂, O₂, H₂, or Ar;
capacitance C of 500 pF; and
bias voltage lying in the range −100 V to −100 kV.

The implantation method using this implanter IMP is analogous to the above method, apart from the absence of the load impedance Z.

In this embodiment, a current generator or capacitor charger is used directly, and charging is stopped once the desired voltage is reached across the terminals of the capacitor. The advantage of this second embodiment lies in eliminating the load impedance Z which constitutes a power consuming element and a source of weakness for the machine.

The invention thus relates to any generator associated with a parallel-connected branch. It consists in restricting this parallel branch to a single capacitor.

On request, the primary and secondary pumps PP and PS achieve the desired vacuum in the enclosure ENV after a substrate SUB has been placed on the substrate-carrier tray PPS.

The pulsed plasma source is generally powered at a radiofrequency of 13.56 megahertz (MHz) ±10%.

The mean implantation current depends on the density of the plasma, on the bias voltage, and on the frequency and the duration of the plasma pulses. For stationary instantaneous conditions, the current can be set by adjusting the pulse repetition period. For implanting at 50 keV, the range over which current can be set should be 1 μA to 100 mA. For implanting at 500 eV, the range should be 1 μA to 10 mA.

The minimum value for the substrate voltage depends firstly on the discharge time, equivalent to the plasma ignition time, and secondly on the capacitance of the capacitor.

The maximum substrate voltage depends on the charge on the capacitor.

An additional characteristic of the implanter shown in FIG. 1 serves to implant uniformly when the substrate is of large size.

As mentioned above, the substrate SUB lies on a substrate-carrier tray PPS that is generally in the form of a disk that is rotatable about its vertical axis AXT. With or without rotation, if the axis AXP of the plasma source ALP above the substrate SUB is close to the axis AXT of the tray PPS, then plasma diffusion will be a maximum along this axis and will present a distribution gradient relative to the axis. The dose implanted in the substrate SUB will present distribution that is not uniform.

If there is an offset between the two axes AXT and AXP, then rotating the substrate-carrier tray PPS enables the substrate SUB to move relative to the axis AXP of the plasma source. The dose implanted in the substrate SUB will then present a distribution in which uniformity is considerably improved.

The effectiveness of this system has been verified for silicon wafers having a diameter of 200 mm, in which the resulting non-uniformity was found to be less than 2.5% when implanting BF₃ at 500 eV and at 10¹⁵ ions/cm².

The embodiments of the invention described above were selected for their concrete nature. Nevertheless, it is not possible to list exhaustively all embodiments covered by the invention. In particular, any means described can be replaced by equivalent means without going beyond the ambit of the present invention.

1. A power supply ALT, ALTi, ALTj for an ion implanter, the power supply comprising an electricity generator SOU placed between a substrate-carrier tray PPS and ground E, the power supply further comprising a capacitor CDS in a parallel branch likewise connected between said substrate-carrier tray PPS and ground E, the power supply being characterized in that said capacitor CDS has capacitance of less than 5 nF.

2. A power supply according to claim 1, characterized in that said parallel branch comprises said capacitor CDS only.

3. A power supply according to claim 1, characterized in that said generator is a voltage generator ALTi, and it includes a load impedance Z in series therewith.

4. A power supply according to claim 3, characterized in that said load impedance Z presents resistance lying in the range 200 kΩ to 2000 kΩ.

5. A power supply according to claim 3, characterized in that the voltage delivered by said generator ALTi lies in the range −100 V to −10,000 V.

6. A power supply according to claim 1, characterized in that said generator is a current generator ALTj.

7. A power supply according to claim 6, characterized in that the voltage delivered by said generator ALTj lies in the range −100 V to −100,000 V.

8. An ion implanter comprising a power supply according to claim 1, and a pulsed plasma source ALP, and characterized in that it includes means for ensuring that the duration of the plasma pulse emitted by said pulsed plasma source ALP lies in the range 20 μs to 5000 μs.

9. An ion implanter comprising a power supply according to claim 6, and a pulsed plasma source ALP, and characterized in that it includes means for ensuring that the duration of the plasma pulse emitted by said pulsed plasma source ALP lies in the range 20 μs to 5000 μs, and in that it includes means for inhibiting said current generator SCC during said plasma pulse.

10. An implanter according to claim 8, characterized in that the electrical impedance of the plasma lies in the range 30 kΩ to 300 kΩ.

11. An implanter according to claim 8, characterized in that the working pressure is less than 5×10⁻³ mbar.

12. An implanter according to claim 8, characterized in that the capacitance C of said capacitor CDS, the duration tp of the pulse produced by said pulsed plasma source ALP, said inversion voltage Vᵢₙᵥ, and the voltage Vₚₛ delivered by said generator ALT, ALTi, ALTj, are governed by the following formula:
C/tP<−1/<Zp.ln(Vᵢₙᵥ/Vₚₛ))

13. An implanter according to claim 8, characterized in that said substrate-carrier tray PPS is rotatable about its axis AXT.

14. An implanter according to claim 13, characterized in that said substrate-carrier tray PPS and said pulsed plasma source ALP present an adjustable offset between their axes.
